(19) United States
(12) Patent Application Publication
(10) Pub. No.: US 2008/0109993 A1
(43) Pub. Date: May 15, 2008

(54) HINGE MODULE FOR AN ELECTRONIC DEVICE AND ELECTRONIC DEVICE HAVING THE SAME

(76) Inventor: Ji Man Myeong, Icheon-Si (KR)

Correspondence Address: F. CHAU & ASSOCIATES, LLC, 130 WOODBURY ROAD, WOODBURY, NY, 11797, US

(21) Appl. No.: 11/930,630

(22) Filed: Oct. 31, 2007

(30) Foreign Application Priority Data
Nov. 10, 2006 (KR) 10-2006-0111137

(51) Int. Cl. E05F 1/08; H05K 7/16

(52) U.S. Cl. 16/277; 361/681

(57) ABSTRACT

A hinge module for an electronic device includes a rotating unit having a rotary shaft, a housing receiving at least a portion of the rotary shaft, and a fixing unit partially inserted into the rotary shaft. A rotation resisting force between the rotary shaft of the rotating unit and the fixing unit partially inserted into the rotary shaft is larger than a rotation resisting force between the housing and the rotary shaft of the rotating unit.

### CROSS-REFERENCE TO RELATED PATENT APPLICATION

This application claims priority to Korean Patent Application No. 2006-0111137, filed on Nov. 10, 2006, the disclosure of which is incorporated by reference herein in its entirety.

### BACKGROUND OF THE INVENTION

1. Technical Field

The present disclosure relates to a hinge module for an electronic device and an electronic device having the same, and more particularly, to a hinge module preventing a distortion of a display panel with respect to a body and maintaining the display panel at a certain position with respect to the body and an electronic device having the same.

2. Discussion of Related Art

A portable terminal includes a display for displaying an image, and a base for generating a control signal. To reduce a size of the portable terminal and to protect its display, the portable terminal is formed as a folding type so that the display is folded with respect to the base. That is, a portable terminal such as, for example, a notebook includes a base having a keyboard and a display connected to the base. The display can be folded and unfolded with respect to the base. The notebook may include a hinge for coupling the display and the base to each other so that the display can rotate with respect to the base.

The hinge used in a portable terminal such as a notebook is used to rotate (i.e., open or close) the display using an external rotating force, and causes the display to be fixed (i.e., held in the open state) when the external rotating force is removed. The hinge fixes the display using an internal frictional force of the hinge. Thus, to rotate the display, a force larger than the internal frictional force of the hinge is applied to the display. However, the force applied to the display may cause the display to be distorted, thereby causing defects such as, for example, pixel damage, driving element damage, film damage, and/or occurrence of impurities in the display panel.

As a size of the display increases, the display has more weight, which requires increased frictional force in the hinge to fix the display at a desired position. Thus, the force applied to rotate the display increases.

### SUMMARY OF THE INVENTION

Exemplary embodiments of the present invention provide a hinge module for an electronic device, which allows smooth opening or closing of a display by minimizing a frictional force between a rotating unit connected to the display and a housing supporting the rotating unit, and prevents unintentional movement of the display by fixing the rotating unit with a fixing unit, and an electronic device having the hinge module.

According to an exemplary embodiment of the present invention, a hinge module for an electronic device includes a rotating unit having a rotary shaft, a housing receiving the rotary shaft, and a fixing unit partially inserted into the rotary shaft.

A rotation resisting force between the rotary shaft of the rotating unit and the fixing unit partially inserted into the rotary shaft may be larger than a rotation resisting force between the housing and the rotary shaft of the rotating unit.

A concave groove can be provided in one end of the rotary shaft, and the fixing unit includes a fixing rod partially inserted into the concave groove.

A longitudinal cross section of the fixing rod may be a rectangular bar shape, and a transverse cross section of the fixing rod may be a polygonal shape or a circular shape having a concavo-convex pattern formed on an outer surface thereof. The fixing rod may have a width that is gradually reduced.

The fixing unit may further include a receiving body having a fixing through hole receiving the fixing rod, and a rotation resisting part provided between the fixing rod and the fixing through hole of the receiving body.

The rotation resisting part may have a hollow cylindrical body, and a rotation resisting force between an outer surface of the body of the rotation resisting means and the fixing through hole can be larger than that between the housing and the rotary shaft of the rotating unit. The body of the rotation resisting part may be formed of an elastic member.

The rotary shaft may have a fixing projecting portion protruding from one end thereof, the fixing unit may include a fixing rod having a concave groove corresponding to the fixing projecting portion, the fixing projecting portion being inserted into the concave groove. A longitudinal cross section of the fixing projecting portion can be a rectangular bar shape, and a transverse cross section of the fixing projecting portion can be a polygonal shape or a circular shape having a concavo-convex pattern formed on an outer surface thereof.

According to an exemplary embodiment of the present invention, an electronic device includes a display, a base, and at least one hinge module, wherein each of the hinge modules includes a housing connected to the base, a rotating unit connected to the display and partially coupled to the housing, and a fixing unit connected to the base and partially inserted into the rotating unit.

A concave groove may be provided in one end of the rotary shaft. The fixing unit may include a fixing rod partially inserted into the concave groove, and a receiving body having a fixing through hole for receiving the fixing rod.

The electronic device may further comprise a rotation resisting part provided between the fixing rod and the receiving body. The rotation resisting part may include a hollow cylindrical body. A rotation resisting force between the fixing through hole and an outer surface of the body can be larger than a frictional force between the rotating unit and the housing. The body of the rotation resisting part may be formed of an elastic member.

The electronic device may further comprise a hook for coupling the display and the base or releasing the display and the base from each other, wherein one side of the fixing rod is connected to the hook through a wire, and the other side of the fixing rod is connected through a or the wire to an elastic member fixed to the display. Fixing rods of a plurality of hinge modules adjacent to each other can be connected to each other through a or the wire passing through the rotating unit.

### BRIEF DESCRIPTION OF THE DRAWINGS

Exemplary embodiments of the present invention can be understood in more detail from the following description taken in conjunction with the accompanying drawings, in which:

FIG. 1 is a perspective view showing a portable terminal according to an exemplary embodiment of the present invention;

FIG. 2 is a perspective view showing a hinge module according to an exemplary embodiment of the present invention;

FIG. 3 is a sectional view showing a hinge module according to an exemplary embodiment of the present invention;

FIG. 4 is a sectional view taken along the line A-A of FIG. 3;

FIG. 5 is a sectional view taken along the line B-B of FIG. 3;

FIG. 6 is a perspective view showing a fixing rod according to an exemplary embodiment of the present invention;

FIGS. 7 to 9 are sectional views showing a fixing rod according to an exemplary embodiment of the present invention;

FIG. 10 is a plan view showing a portable terminal according to an exemplary embodiment of the present invention;

FIG. 11 is a sectional view partially showing a hinge module according to an exemplary embodiment of the present invention;

FIG. 12 is a sectional view showing a hinge module according to an exemplary embodiment of the present invention;

FIG. 13 is a sectional view taken along the line C-C of FIG. 12;

FIG. 14 is a sectional view taken along the line D-D of FIG. 12;

FIGS. 15 and 16 are views illustrating an operation of the hinge module according to an exemplary embodiment of the present invention;

FIG. 17 is a sectional view showing a hinge module according to an exemplary embodiment of the present invention;

FIG. 18 is a sectional view taken along the line E-E of FIG. 17; and

FIG. 19 is a sectional view showing a hinge module according to an exemplary embodiment of the present invention.

### DETAILED DESCRIPTION OF EXEMPLARY EMBODIMENTS

Exemplary embodiments of the present invention will be understood below in more detail with reference to the accompanying drawings. The present invention may be embodied in many different forms and should not be construed as limited to the embodiments set forth herein.

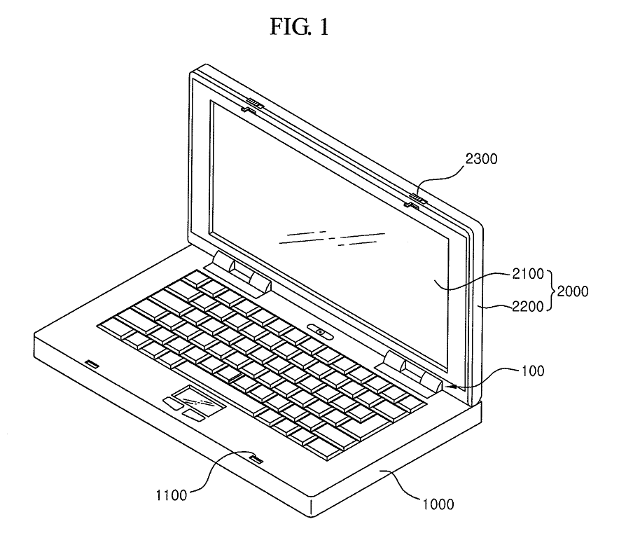

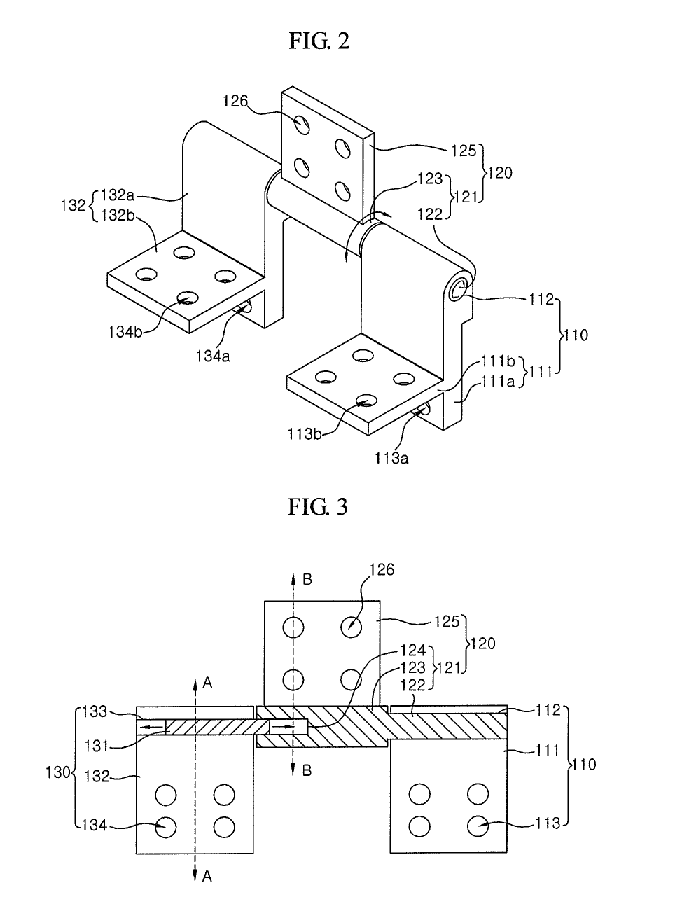

Referring to FIGS. 1 to 6, a portable terminal according to an exemplary embodiment of the present invention includes a base 1000, a display 2000, and a hinge module 100. The hinge module 100 couples the base 1000 and the display 2000 to be rotatable with respect to each other.

The base 1000 may include, for example, a main board, a central process unit (CPU), various chipsets, a storage device such as, for example, a hard disk, data input device such as, for example, a keyboard and a touch pad, and a battery for supplying power. The display 2000 may include a display panel 2100 for displaying an image, and a housing 2200 for protecting the display panel 2100. The display 2000 includes a hook 2300 partially protruding toward the base 1000. The base 1000 includes a hook receiving hole 1100 for receiving the hook 2300. The hook 2300 is received in the hook receiving hole 1100, so that the display 2000 may be coupled to the base 1000. The display 2000 and the base 1000 can be coupled to each other using a variety of coupling members, including, but not limited to, the hook 2300.

The hinge module 100 is coupled to at least one side of the base 1000 and the display 2000 so that the base 1000 and the display 2000 can be opened or closed with respect to each other.

The hinge module 100 includes a housing 110, a rotating unit 120, and a fixing unit 130.

The housing 110 includes a housing body 111, and a rotation through hole 112 provided in a portion of the housing body 111. One end of the housing body 111 is fixed to the base 1000 through fastening members (not shown). In an exemplary embodiment, the housing body 111 can be fixed to the base 1000 with screws. Screw holes 113a and 113b are provided in one end of the housing body 111. Here, the housing body 111 includes a first plate 111a extending in one direction, and a second plate 111b extending in a direction substantially perpendicular to the first plate 111a. The rotation through hole 112 is provided in an upper portion of the first plate 111a, and a plurality of screw holes 113a are provided in a lower portion thereof. A plurality of screw holes 113b are also provided in the second plate 111b. In an exemplary embodiment, a concave groove can be used instead of the rotation through hole 112.

The rotating unit 120 includes a rotary shaft 121 and a fixing plate 125. The rotary shaft 121 is partially inserted into the housing 110 to be rotatable, and can be fixed by the fixing unit 130. The rotary shaft 121 includes a first circular rotary shaft 123 of a cylindrical shape, a second circular rotary shaft 122 extending from one end of the first circular rotary shaft 123, and a fixing recess 124 provided in the other end of the first circular rotary shaft 123. The second circular rotary shaft 122 is inserted into the rotation through hole 112 of the housing 110. Accordingly, the rotary shaft 121 is prevented from being dislocated when the rotating unit 120 is rotated. The second circular rotary shaft 122 can have a diameter smaller than that of the first circular rotary shaft 123. The fixing plate 125 is formed in a plate shape extending from the first circular rotary shaft 123. The fixing plate 125 is fixed to the display 2000 with fastening members such as, for example, screws (not shown). A plurality of screw holes 126 are provided in the fixing plate 125. The rotary shaft 121 of the rotating unit 120 can be rotated in the rotation through hole 112 of the housing body 111 substantially without rotating resistance (i.e., without friction). The rotary shaft 121 may rotate in the rotation through hole 112 with a small amount of force. The rotating resistance is a force hindering the rotary shaft 121 of the rotating unit 120 from being rotated. Thus, the base 1000 and the display 2000 can be opened or closed smoothly. The rotary shaft 121 and the rotation through hole 112 may comprise frictionless material, or a lubricating member is provided between the rotary shaft 121 and the rotation through hole 112 to reduce a frictional force therebetween. In an exemplary embodiment, the rotary shaft 121 and the rotation through hole 112 can be configured to form a point or line contact with each other, thereby reducing the friction therebetween.

The fixing unit 130 includes a fixing rod 131 and a receiving body 132 for receiving the fixing rod 131. One end of the receiving body 132 is fixed to the base 1000 with fastening members (not shown) such as, for example, screws. A fixing through hole 133 is provided in one side of the receiving body 132 to receive the fixing rod 131. The fixing rod 131 is received in the fixing through hole 133 of the receiving body 132. The fixing rod 131 moves forwardly or backwardly (i.e., in the horizontal direction) in the fixing through hole 133 by an external force and partially protrudes out of the fixing through hole 133. A predetermined projection or protruding prevention plate (not shown) may be provided in one side of the fixing through hole 133 to prevent the fixing rod 131 from protruding. The receiving body 132 includes a first extension plate 132a extending in one direction, and a second extension plate 132b extending substantially perpendicular to the first extension plate 132a. A plurality of screw holes 134a and 134b are provided in the first and second extension plates 132a and 132b.

The fixing rod 131 protruding out of the fixing through hole 133 is inserted into a fixing recess 124 provided in the rotary shaft 121 of the rotating unit 120. The rotary shaft 121 can be fixed by the fixing rod 131 inserted into the fixing recess 124 of the rotary shaft 121.

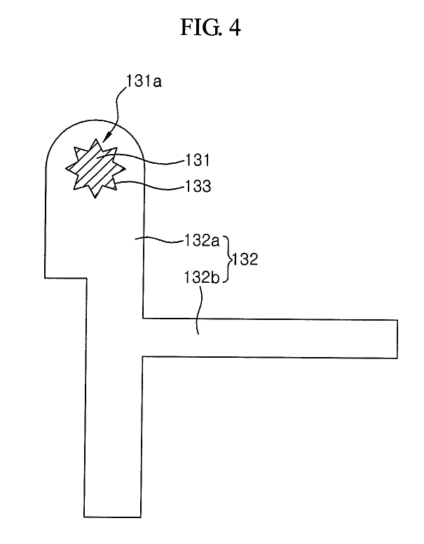

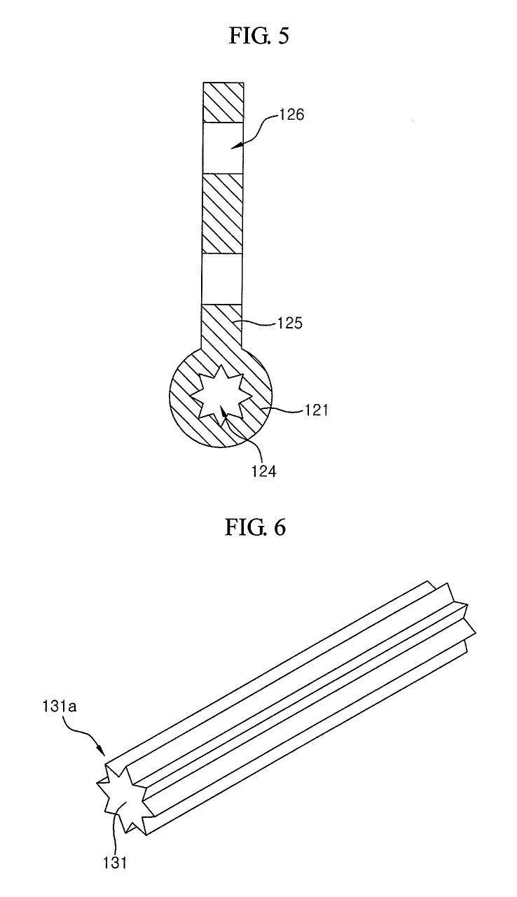

The fixing rod 131 has toothed fixing protrusions 131a on its surface as shown in FIG. 6. A longitudinal cross section of the fixing rod 131 is substantially in the shape of a rectangle as shown in FIG. 3, and a transverse cross section thereof is in the shape of a circle having teeth formed on the outer surface thereof as shown in FIGS. 4 and 5. The fixing through hole 133 of the receiving body 132 and the fixing recess 124 of the rotary shaft 121 of the rotating unit 120 are formed in a shape corresponding to the fixing rod 131. That is, transverse cross sections of the fixing through hole 133 and the fixing recess 124 are shaped corresponding to the teeth of the fixing rod 131. The fixing rod 131 having the toothed fixing protrusions 131a on its surface can move forwardly or backwardly between the fixing through hole 133 of the receiving body 132 and the fixing recess 124 of the rotary shaft 121. In an exemplary embodiment, the fixing rod 131 can move forwardly or backwardly by an external force, and thus can be moved into or out of the fixing recess 124 of the rotating unit 120. The toothed fixing protrusions 131a are inserted and fixed in the fixing recess 124 of the rotating unit 120. Thus, it is possible to fix the rotary shaft 121 of the rotating unit 120.

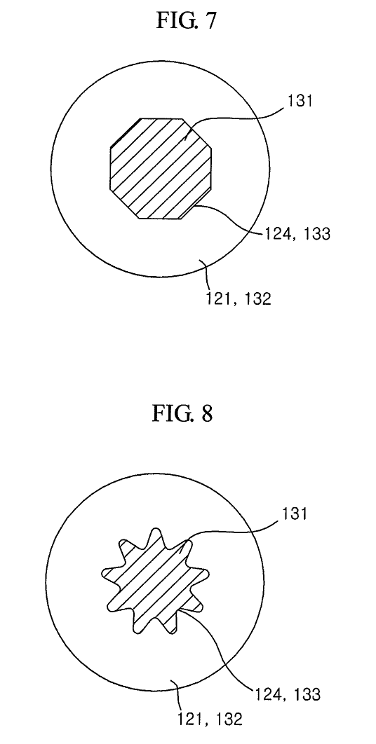

The fixing rod 131 may have a variety of transverse cross sectional shapes according to exemplary embodiments of the present invention. That is, the transverse cross section of the fixing rod 131 may be a polygonal shape as shown in FIG. 7. The transverse cross section of the fixing rod 131 may be a substantially circular shape with a concavo-convex pattern having a plurality of protrusions formed on its surface as shown in FIG. 8. In an exemplary embodiment, the fixing rod 131 can be formed having a point symmetry.

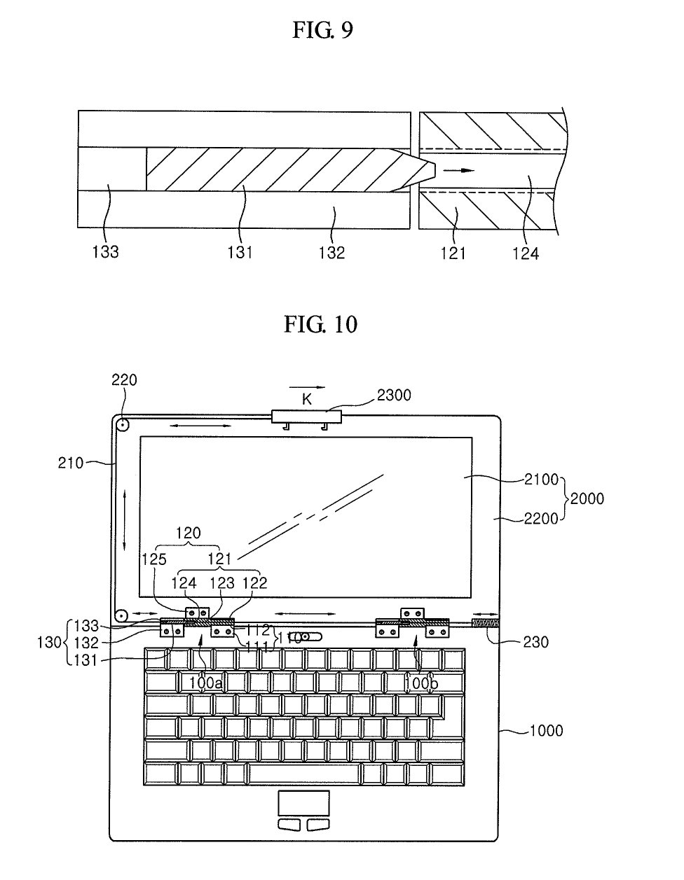

Grooves corresponding to the fixing protrusions 131a of the fixing rod 131 are provided in the fixing recess 124 of the rotating unit 120. Thus, if the fixing protrusions 131a of the fixing rod 131 are not exactly aligned with the grooves of the fixing recess 124, the fixing rod 131 cannot be inserted into the fixing recess 124. Thus, the fixing rod 131 can have a sharp end as shown in FIG. 9. That is, the fixing rod 131 can be formed to have a width in its center portion substantially identical to that of the fixing through hole 133 of the fixing unit 130 and the fixing recess 124 of the rotating unit 120, and to have a width in its end portion smaller than that of the center portion thereof. The width of the fixing rod 131 can be gradually reduced from its center portion to the end portions. Accordingly, if any alignment error occurs between the fixing protrusions 131a of the fixing rod 131 and the grooves of the fixing recess 124, the end of the fixing rod 131 can be inserted into the fixing recess 124, and then the alignment error may be corrected when the center portion of the fixing rod 131 is further inserted thereinto.

In an exemplary embodiment, the rotation of the rotating unit 120 may be stopped by inserting the fixing rod 131 into the fixing recess 124. Accordingly, it is possible to constantly maintain an angle of the display 2000 in its open state. The rotating unit 120 may rotate smoothly by releasing the fixing rod 131 from the fixing recess 124. Thus, the base 1000 and the display 2000 may be opened or closed with a small amount of force.

In an exemplary embodiment, it is possible to insert or withdraw the fixing rod 131 into or from the fixing recess 124 of the rotating unit 120 using an external pushing force and a restoring force of an elastic member. That is, as shown in FIG. 10, the fixing rod 131 is connected to the hook 2300 of the display 2000 through a wire 210, and a predetermined elastic member 230 is provided in an end of the wire 210. The elastic member 230 is fixed to one side of the display 2000.

For a force applied to the hook 2300 to be smoothly transferred to the fixing rod 131, a plurality of pulleys 220 may be provided. When a user pushes the hook 2300 in a direction K shown in FIG. 10, the wire 210 is also pulled in the direction K. The pushing force applied to the hook 2300 is changed in direction by the plurality of pulleys 220. Then, the pushing force is applied to the fixing rod 131. Using the pushing force, the fixing rod 131 is withdrawn from the fixing recess 124 of the rotating unit 120. The elastic member 230 connected to the end of the wire 210 extends. Thus, the display 2000 can be easily opened or closed using a small amount of force.

When the pushing force applied to the hook 2300 is released, the extending elastic member 230 is restored to its initial state. The restoring force of the elastic member 230 is applied to the fixing rod 131 through the wire 210, thereby causing the fixing rod 131 to be inserted into the fixing recess 124 of the rotating unit 120. The restoring force moves the hook 2300 in a direction opposite to the direction K through the wire 210. In an exemplary embodiment, the fixing rod 131 can be moved using the pushing force applied from the outside and the restoring force of the elastic member 230. Accordingly, the display 2000 can be fixed at a certain position.

In FIG. 10, the single hook 2300 is provided on the display 2000. However, two or more hooks 2300 may also be employed as shown in FIG. 1. In an exemplary embodiment, the base 1000 and the display 2000 are connected to be opened or closed using the two hinge modules 100. The fixing rods 131 of the two hinge modules 100 (100a, 100b) are connected to each other through the wire 210.

The wire 210 is connected to one side of the fixing rod 131 of the hinge module 100a, passes through the rotating unit 120, and is the connected to one side of the fixing rod 131 of the hinge module 100b adjacent to the hinge module 100a. The other side of the fixing rod 131 of the hinge module 100a is connected to the hook 2300 through the wire 210. The other side of the fixing rod 131 of the hinge module 100b is connected to the elastic member 230 through the wire 210 passing through the rotating unit 120 of the hinge module 100b. A wire through hole is provided in the rotating unit 120 so that the wire 210 may pass through the wire through hole.

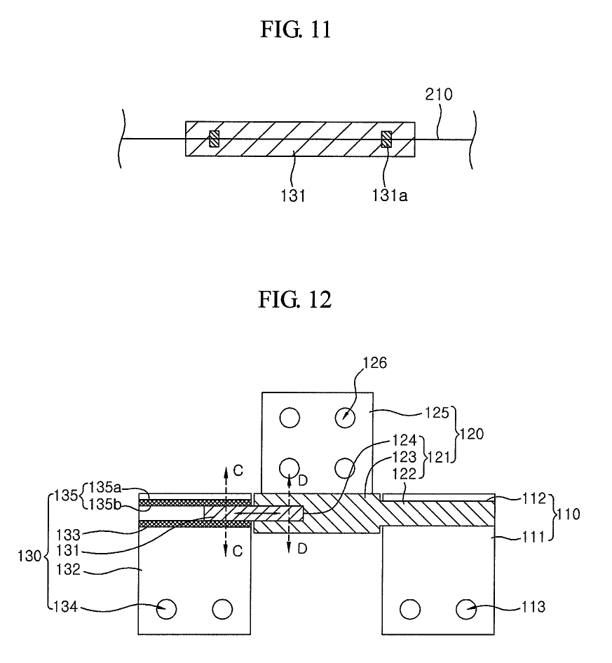

The wire 210 may extend to pass through the fixing rod 131. That is, as shown in FIG. 11, a wire fixing portion 131a is provided in the fixing rod 131 so that the wire 210 is fixed to the fixing rod 131. Thus, the movement of the wire 210 may be transferred to the fixing rod 131. In an exemplary embodiment, a separate fixing member (not shown) may be provided outside the fixing rod 131 to fix the wire 210 and the fixing rod 131. In an exemplary embodiment, the fixing rod 131 and the wire 210 may also be integrally formed.

In an exemplary embodiment, there may be provided a driving member (not shown) for moving the fixing rod 131 at a side of the display 2000, instead of the hook 2300. That is, if a user pulls the driving member, the fixing rod 131 inserted into the fixing recess 124 of the rotating unit 120 is withdrawn out of the fixing recess 124 by the user's pulling force, and then the user can open the display 2000 or control its opened angle. Thereafter, if the user releases the driving member, the fixing rod 131 may be inserted into the fixing recess 124 of the rotating unit 120 by the elastic member 230. The driving member may include a motor, so that the fixing rod 131 can be inserted into or withdrawn out of the fixing recess 124 of the rotating unit 120 by changing a rotating force of the motor into a horizontal movement. The fixing rod 131 may also be inserted into or withdrawn out of the fixing recess 124 of the rotating unit 120 by pushing or pulling the fixing rod 131 using, for example, a magnetic force. An additional elastic member may also be provided in the fixing through hole 133. With the additional elastic member, the fixing rod 131 may be inserted into the rotary shaft 121 of the rotating unit 120 when an external force is not applied. The fixing rod 131 may be withdrawn out of the rotary shaft 121 of the rotating unit 120 when an external force is applied thereto.

In an exemplary embodiment, a rotation resisting device may be provided between the fixing rod of the fixing unit and the receiving body so that the fixing rod can be rotated when a rotating force larger than a resisting force given by the rotation resisting device is applied thereto.

Referring to FIGS. 12 to 16, the hinge module according to an exemplary embodiment of the present invention includes a housing 110 having a rotation through hole 112 formed therein, a rotating unit 120 partially inserted into the rotation through hole 112 to be rotatable and having a fixing recess 124 formed in its one side, and a fixing unit 130 having a fixing rod 131 inserted into the fixing recess 124 to fix the rotating unit 120. The fixing unit 130 may include a receiving body 132 having a fixing through hole 133 for receiving the fixing rod 131, and a rotation resisting part 135 provided in at least a portion between the fixing rod 131 and the fixing through hole 133.

The rotation resisting part 135 is formed in a hollow cylindrical shape (e.g., a pipe shape), and the fixing rod 131 is inserted into an inner space 135b of the cylinder 135a. In an exemplary embodiment, a rotation resisting force of a certain level exists between the rotation resisting part 135 and the fixing through hole 133. Accordingly, the rotation resisting part 135 is rotated only when a rotating force applied to the rotation resisting part 135 is larger than the rotation resisting force.

In an exemplary embodiment, the rotation resisting part 135 may comprise various kinds of elastic members. The elastic member may be formed of rubber or a spring. That is, it is possible that a rotation resisting part 135 comprising rubber is inserted between the fixing through hole 133 and the fixing rod 131 so that the rotation resisting part 135 of rubber is not rotated in the fixing through hole 133. When a spring is used as the rotation resisting part 135, the rotation resisting part 135 may further include a protection member (not shown) surrounding the fixing rod 131 and thus receives a rotating force of the fixing rod 131. The rotation resisting force refers to a force hindering the rotation of the rotation resisting part 135, which is the sum of a frictional force caused by the contact between the fixing through hole 133 and the elastic member and a force with which the elastic member pulls the fixing rod 131 relative to the fixing through hole 133 therebetween. The rotation resisting force may be any one of the frictional force and the pulling force of the elastic member. The rotation resisting part 135 may comprise a material with a large rotation resisting force against the fixing through hole 133. An elastic member or a material having a large rotation resisting force may be inserted between the rotation resisting part 135 and the fixing through hole 133.

The fixing rod 131 has a toothed concavo-convex pattern formed on its surface, as described in connection with FIGS. 4-8. Thus, the inner space 135b of the rotation resisting part 135 has a concavo-convex portion corresponding to the concavo-convex pattern of the fixing rod 131. Accordingly, the fixing rod 131 can be moved forwardly or backwardly in its longitudinal direction in the inner space 135b of the rotation resisting part 135. The fixing rod 131 may be inserted into or withdrawn out of the fixing recess 124 of the rotating unit 120. A frictional force between the fixing rod 131 and the rotation resisting part 135 is reduced so that the fixing rod 131 may be inserted into or withdrawn out of the fixing recess 124 of the rotating unit 120.

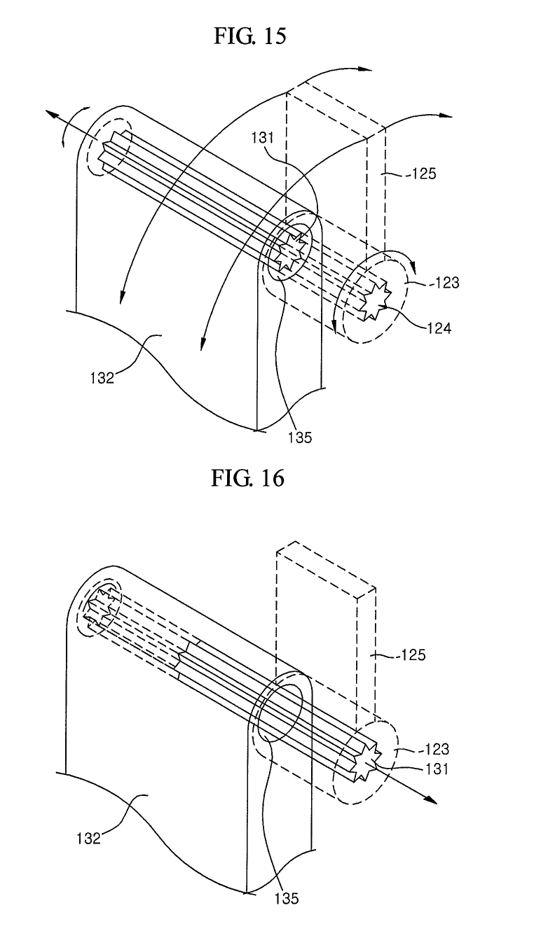

In an exemplary embodiment, when the fixing rod 131 is withdrawn from the fixing recess 124 of the rotating unit 120 by an external force and then inserted into the inner space 135b of the rotation resisting part 135 as shown in FIG. 15, the mechanical coupling between the fixing unit 130 and the rotating unit 120 is released. Accordingly, it is possible to rotate the rotating unit 120 by a small amount of force after withdrawing the fixing rod 131 out of the fixing recess 124 of the rotating unit 120 because a frictional force between the rotary shaft 121 of the rotating unit 120 and the rotation through hole 122 of the housing 110 is small.

When the fixing rod 131 is partially inserted into the fixing recess 124 of the rotating unit 120 by an external force as shown in FIG. 16, whether or not the rotating unit 120 is rotated is determined depending on the magnitude of the rotating force applied to the fixing rod 131 through the rotating unit 120. As shown in FIG. 14, the fixing recess 124 of the rotating unit 120 has a concavo-convex portion corresponding to the concavo-convex pattern of the fixing rod 131 described above. Thus, the rotating force applied to the rotary shaft 121 of the rotating unit 120 from the outside is supplied to the fixing rod 131.

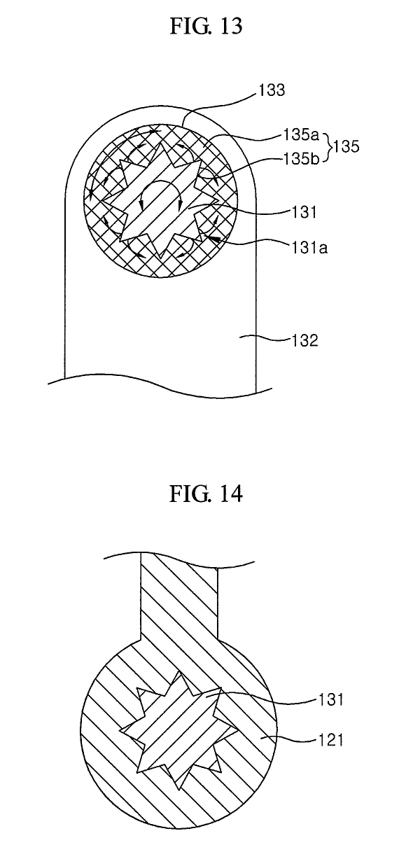

In an exemplary embodiment, the fixing rod 131 is partially positioned inside the rotation resisting part 135. Thus, as shown in FIG. 13, the rotating force applied to the fixing rod 131 through the rotating unit 120 is applied to the rotation resisting part 135. The rotation resisting part 135 and the fixing rod 131 can be rotated together or may not rotate depending on the magnitude of the rotating force applied to the rotation resisting part 135.

That is, when the rotating force applied to the rotation resisting part 135 is larger than the rotation resisting force between the rotation resisting part 135 and the fixing through hole 133, the rotation resisting part 135 is rotated, whereby the fixing rod 131 and the rotating unit 120 are rotated together. If the rotating force applied to the rotation resisting part 135 is smaller than the rotation resisting force between the rotation resisting part 135 and the fixing through hole 133, the rotation resisting part 135 is not rotated, whereby the fixing rod 131 and the rotating unit 120 are not rotated.

According to an exemplary embodiment of the present invention, the magnitude of a rotating force used for rotating the rotating unit 120 can be changed according as the fixing rod 131 of the fixing unit 130 is inserted into or withdrawn from the fixing recess 124 of the rotating unit 120. Accordingly, the rotating unit 120 can be rotated using a small amount of force, and a rotation angle of the rotating unit 120 may be constantly maintained. When an excessive external force is applied, the fixing rod 131 is rotated together with the rotating unit 120, thereby preventing the fixing rod 131 from being broken. The fixing rod 131 can have a strength larger than the rotation resisting force.

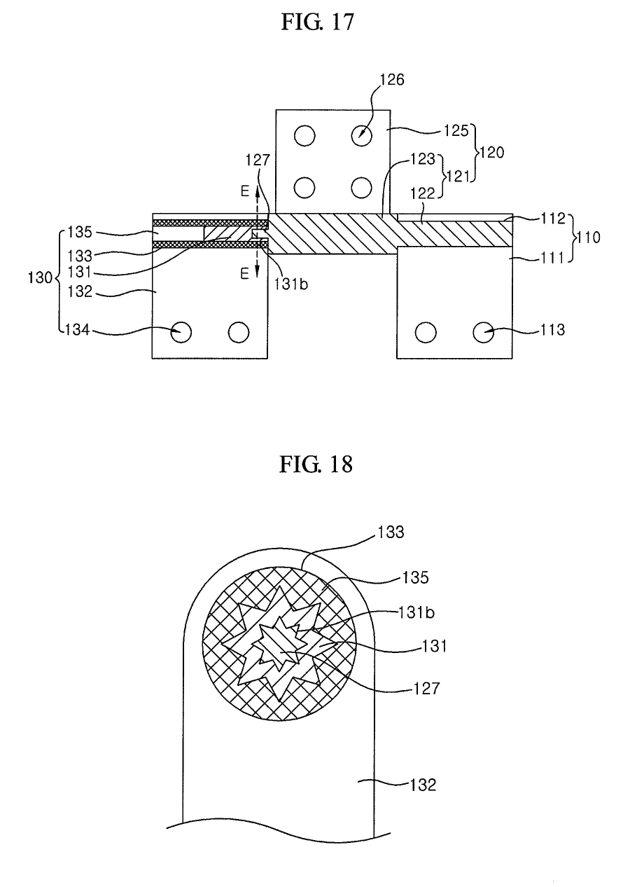

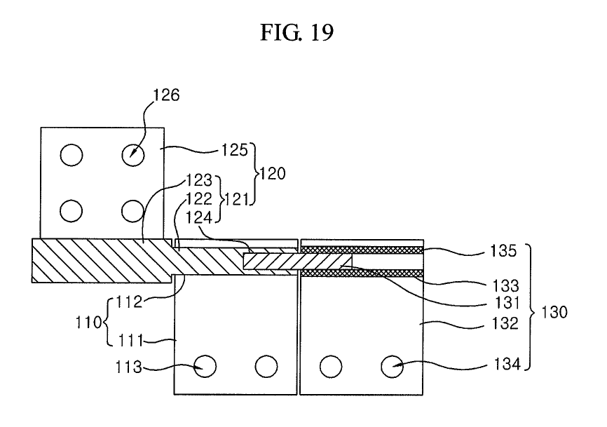

Referring to FIGS. 17 and 18, a fixing projecting portion 127, instead of the fixing recess 124, may be formed on one end of the rotating unit 120. A concave groove 131b corresponding to the fixing projecting portion 127 is provided in one side of the fixing rod 131. The fixing rod 131 is moved forwardly or backwardly in its longitudinal direction. Accordingly, the fixing projecting portion 127 of the rotating unit 120 may be inserted into or withdrawn out of the concave groove 131b of the fixing rod 131.

When the fixing rod 131 is moved by an external force and thus the fixing projecting portion 127 of the rotating unit 120 is withdrawn out of the concave groove 131b of the fixing rod 131, the rotating unit 120 can be rotated by a small rotating force. When the fixing rod 131 is moved by an external force and thus the fixing projecting portion 127 of the rotating unit 120 is inserted into the concave groove 131b of the fixing rod 131, the rotating unit 120 is not easily rotated or is rotated by a large amount of rotating force. That is, a predetermined concavo-convex pattern is provided on the surface of the fixing projecting portion 127, and a concavo-convex portion corresponding to the concavo-convex pattern is provided in the concave groove 131b of the fixing rod 131. A rotating force of the rotating unit 120, namely a rotating force of the fixing projecting portion 127, is applied to the concave groove 131b of the fixing rod 131 through the concavo-convex patterns, and then, the rotating force applied to the fixing rod 131 is applied to the rotation resisting part 135. When the rotating force is smaller than the rotation resisting force of the rotation resisting part 135, the rotating force is offset. If the rotating force is larger than the rotation resisting force of the rotation resisting part 135, the rotation resisting part 135 is rotated by the rotating force. Accordingly, the fixing rod 131, the fixing projecting portion 127 and the rotary shaft 121 of the rotating unit 120 are rotated.

In the hinge module of this exemplary embodiment as shown in FIG. 10, the fixing recess 124 may be provided in the rotary shaft 121 of the rotating unit 120 which is rotatably inserted into the housing 110. That is, the rotary shaft 121 of the rotating unit 120 includes a first circular rotary shaft 123 and a second circular rotary shaft 122, wherein the second circular rotary shaft 122 is rotatably inserted into the rotation through hole 112 of the housing 110. Thus, in an exemplary embodiment, the fixing recess 124 is provided in the second circular rotary shaft 122, so that the fixing rod 131 of the fixing unit 130 is inserted into or withdrawn out of the fixing recess 124.

When the fixing rod 131 of the fixing unit 130 is inserted into the fixing recess 124 of the second circular rotary shaft 122, the rotating unit 120 (i.e., the second circular rotary shaft 122) is rotated only when a rotating force applied to the rotating unit 120 is larger than a rotation resisting force of the rotation resisting part 135 of the fixing unit 130. When the fixing rod 131 of the fixing unit 130 is withdrawn out of the fixing recess 124 of the second circular rotary shaft 122, the rotating unit 120 can be rotated by a small amount of rotating force.

The rotating unit 120 of the hinge module 100 according to an exemplary embodiment is connected to the display 2000 of a portable terminal, while the housing 110 and the fixing unit 130 are connected to the base 1000. In an exemplary embodiment, by withdrawing the fixing rod 131 of the hinge module 100 from the fixing recess 124 of the rotating unit 120 when the display 2000 is opened, the display 2000 can be opened (moved) by a small amount of force. Thus, it is possible to prevent the display from being distorted caused from an excessive force when opening the display 2000.

After the display 2000 is opened, by inserting the fixing rod 131 of the hinge module 100 into the fixing recess 124 of the rotating unit 120, the display 2000 can be constantly maintained at an angle in its opened (moved) state. In an exemplary embodiment, when the display 2000 is rotated by applying an external force in a state where the fixing rod 131 of the hinge module 100 is not withdrawn from the rotating unit 120, depending on the magnitude of the applied force, the display 2000 can be moved, or maintained in a position without movement. Thus, it is possible to prevent the fixing rod 131 from being broken by an excessive external force.

According to an exemplary embodiment of the present invention, the hinge module may change the magnitude of a rotating force required for rotating the rotating unit according to a coupling relationship between the rotating unit attached to the display and the fixing unit attached to the base.

According to an exemplary embodiment of the present invention, the rotating rod of the fixing unit is partially inserted into the rotating unit to prevent the rotating unit from being inadvertently rotated, so that it is possible to constantly maintain an opened angle of the display. By withdrawing the fixing rod of the fixing unit inserted into the rotating unit therefrom, it is possible to smoothly rotate the rotating unit by a small rotating force, thereby preventing distortion of the display.

According to an exemplary embodiment of the present invention, the fixing rod of the fixing unit for fixing the movement (i.e., rotation) of the rotating unit is rotated depending on the magnitude of an applied force (rotating force), thereby preventing the fixing rod from being broken by the external force.

Although exemplary embodiments have been described with reference to the accompanying drawings, it is to be understood that the present invention is not limited to these precise embodiments, but various changes and modifications can be made by one skilled in the art without departing from the spirit and scope of the present invention. All such changes and modifications are intended to be included within the scope of the invention as defined by the appended claims.

What is claimed is:

1. A hinge module for an electronic device, comprising:
a rotating unit having a rotary shaft;
a housing receiving at least a portion of the rotary shaft; and
a fixing unit partially inserted into the rotary shaft.

2. The hinge module for an electronic device of claim 1, wherein a rotation resisting force between the rotary shaft of the rotating unit and the fixing unit partially inserted into the rotary shaft is larger than a rotation resisting force between the housing and the rotary shaft of the rotating unit.

3. The hinge module for an electronic device of claim 1, wherein a concave groove is provided in one end of the rotary shaft, and the fixing unit includes a fixing rod partially inserted into the concave groove.

4. The hinge module for an electronic device of claim 3, wherein a longitudinal cross section of the fixing rod is a rectangular bar shape, and a transverse cross section of the fixing rod is a polygonal shape or a circular shape having a concavo-convex pattern formed on an outer surface thereof.

5. The hinge module for an electronic device of claim 3, wherein the fixing rod has a width that is gradually reduced.

6. The hinge module for an electronic device of claim 3, wherein the fixing unit further includes a receiving body having a fixing through hole receiving the fixing rod, and a rotation resisting part provided between the fixing rod and the fixing through hole of the receiving body.

7. The hinge module for an electronic device of claim 6, wherein the rotation resisting part has a hollow cylindrical body, and a rotation resisting force between an outer surface of the body and the fixing through hole is larger than a rotation resisting force between the housing and the rotary shaft of the rotating unit.

8. The hinge module for an electronic device of claim 7, wherein the body of the rotation resisting part comprises an elastic member.

9. The hinge module for an electronic device of claim 1, wherein the rotary shaft has a fixing projecting portion protruding from one end thereof, the fixing unit includes a fixing rod having a concave groove corresponding to the fixing projecting portion, the fixing projecting portion being inserted into the concave groove, and a longitudinal cross section of the fixing projecting portion is a rectangular bar shape, and a transverse cross section of the fixing projecting portion is a polygonal shape or a circular shape having a concavo-convex pattern formed on an outer surface thereof.

10. An electronic device, comprising:
a display;
a base; and
at least one hinge module,
wherein the at least one hinge module includes:
a housing connected to the base;
a rotating unit connected to the display and partially coupled to the housing; and
a fixing unit connected to the base and partially inserted into the rotating unit.

11. The electronic device of claim 10, wherein a concave groove is provided in one end of the rotary shaft, and the fixing unit includes a fixing rod partially inserted into the concave groove, and a receiving body having a fixing through hole for receiving the fixing rod.

12. The electronic device of claim 11, further comprising a rotation resisting part provided between the fixing rod and the receiving body.

13. The electronic device of claim 12, wherein the rotation resisting part includes a hollow cylindrical body, and a rotation resisting force between the fixing through hole and an outer surface of the body is larger than a frictional force between the rotating unit and the housing.

14. The electronic device of claim 13, wherein the body of the rotation resisting part is formed of an elastic member.

15. The electronic device of claim 11, further comprising a hook for coupling the display and the base or releasing the display and the base from each other, wherein one side of the fixing rod is connected to the hook through a wire, and the other side of the fixing rod is connected through the wire to an elastic member fixed to the display.

16. The electronic device of claim 15, wherein fixing rods of a plurality of hinge modules adjacent to each other are connected to each other through the wire passing through the rotating unit.
